(19) United States
(12) Patent Application Publication
(10) Pub. No.: US 2024/0153974 A1
(43) Pub. Date: May 9, 2024

(54) IMAGE SENSOR

(71) Applicant: SAMSUNG ELECTRONICS CO., LTD., Suwon-si (KR)

(72) Inventors: Junghyun KIM, Suwon-si (KR); Jonghoon PARK, Suwon-si (KR); Yunki LEE, Suwon-si (KR); Junsik LEE, Suwon-si (KR)

(21) Appl. No.: 18/386,328

(22) Filed: Nov. 2, 2023

(30) Foreign Application Priority Data
Nov. 4, 2022 (KR) 10-2022-0146385

(51) Int. Cl. H01L 27/146

(52) U.S. Cl. CPC H01L 27/14621; H01L 27/14603; H01L 27/14627; H01L 27/14645

(57) ABSTRACT

An image sensor comprising a plurality of first photoelectric conversion regions corresponding to a plurality of first subpixels, a first color filter region above the plurality of first photoelectric conversion regions, and a first microlens above the first color filter region, wherein, the first color filter region includes a first grid structure at a central portion of the first color filter region, and a height of the first grid structure is smaller than a height of the first color filter region.

### CROSS-REFERENCE TO RELATED APPLICATION

Korean Patent Application No. 10-2022-0146385, filed on Nov. 4, 2022, in the Korean Intellectual Property Office, is incorporated by reference herein in its entirety.

### BACKGROUND

### 1. Field

An image sensor is disclosed.

### 2. Description of the Related Art

Image sensors that capture images and convert images into electrical signals are used in electronic devices for general consumers, such as digital cameras, mobile phone cameras, and portable camcorders, and also used in cameras mounted on cars, security devices, and robots.

### SUMMARY

Embodiments are directed to an image sensor including a plurality of first photoelectric conversion regions corresponding to a plurality of first subpixels, a first color filter region above the plurality of first photoelectric conversion regions, and a first microlens above the first color filter region, wherein the first color filter region includes a first grid structure at a central portion of the first color filter region, and a height of the first grid structure is smaller than a height of the first color filter region.

Embodiments are directed to an image sensor including a photoelectric conversion region corresponding to N*N subpixels, a color filter region above the photoelectric conversion region, and a microlens above the color filter region, wherein the photoelectric conversion region includes a first separation element surrounding the photoelectric conversion region, a second separation element in contact with a first side surface of the first separation element, in the photoelectric conversion region, and extending in an X-axis direction, a third separation element in contact with a second side surface of the first separation element, in the photoelectric conversion region, and extending in a Y-axis direction, a fourth separation element in contact with a third side surface of the first separation element, in the photoelectric conversion region, and extending in the X-axis direction, and a fifth separation element in contact with a fourth side surface of the first separation element, in the photoelectric conversion region, and extending in the Y-axis direction, the second separation element, the third separation element, the fourth separation element, and the fifth separation element is not in contact with each other, and the color filter region includes a grid structure arranged at a central portion of the color filter region.

Embodiments are directed to an image sensor including a plurality of photoelectric conversion regions corresponding to a plurality of subpixels, a color filter region above the plurality of photoelectric conversion regions, and a microlens above the color filter region, wherein the color filter region includes a grid structure, the microlens is shifted in a first direction, and the grid structure is shifted in the first direction with respect to a central portion of the color filter region.

### BRIEF DESCRIPTION OF THE DRAWINGS

Features will become apparent to those of skill in the art by describing in detail exemplary embodiments with reference to the attached drawings in which:

FIG. 1 is a block diagram of an image sensor according to an example embodiment.

FIG. 2 is a diagram of a pixel array corresponding to a color filter array, according to an example embodiment.

FIG. 3A is a diagram of a planar layout of an image sensor according to an example embodiment.

FIG. 3B is an example of a cross-sectional view of the layout taken along line A-A′ of FIG. 3A.

FIG. 3C is an example of a cross-sectional view of the layout taken along line A-A′ of FIG. 3A.

FIGS. 4 to 8 are diagrams of planar layouts of image sensors according to example embodiments.

FIGS. 9 and 10 are diagrams of a grid structure arranged in a pixel array, according to an example embodiment.

FIGS. 11A and 11B are diagrams of an image sensor according to an example embodiment.

FIG. 12A is a diagram of a planar layout of an image sensor according to an example embodiment.

FIG. 12B is a cross-sectional view of the layout taken along line B-B′ of FIG. 12A.

FIG. 13 is a diagram of a planar layout of an image sensor according to an example embodiment.

### DETAILED DESCRIPTION

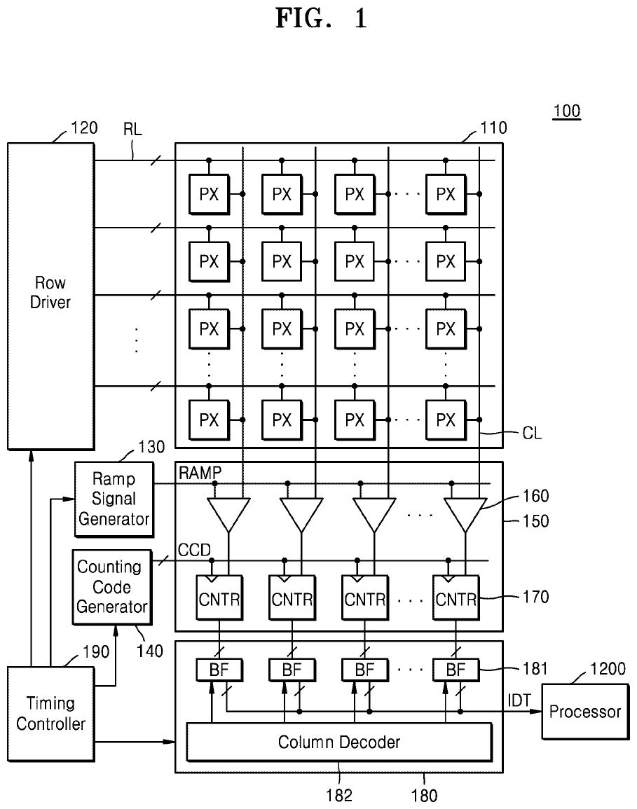

FIG. 1 is a block diagram of an image sensor according to an example embodiment. An image sensor 100 may be a complementary metal oxide semiconductor (CMOS) image sensor (CIS), which may convert an optical signal into an electrical signal.

Referring to FIG. 1, the image sensor 100 may include a pixel array 110, a row driver 120, a ramp signal generator 130, a counting code generator 140, an analog-to-digital conversion circuit 150 (hereinafter, referred to as an ADC circuit), a data output circuit 180, and a timing controller 190. A configuration including the ADC circuit 150 and the data output circuit 180 may be referred to as a readout circuit. The pixel array 110 may include a plurality of row lines RL, a plurality of column lines CL, and a plurality of pixels PX. The plurality of pixels PX may be connected to the plurality of row lines RL and the plurality of column lines CL, and may be arranged in a matrix.

Each of the plurality of pixels PX included in the pixel array 110 may include at least one photoelectric conversion element, and the pixel PX may sense light by using a photoelectric conversion element and output an image signal which may be an electrical signal according to the sensed light. In an implementation, the photoelectric conversion element may include a photodiode, a phototransistor, a photo gate, or a pinned photodiode. Description is given under an assumption that the photoelectric conversion element is a photodiode. As used herein, the term “or” is not an exclusive term, e.g., “A or B” would include A, B, or A and B.

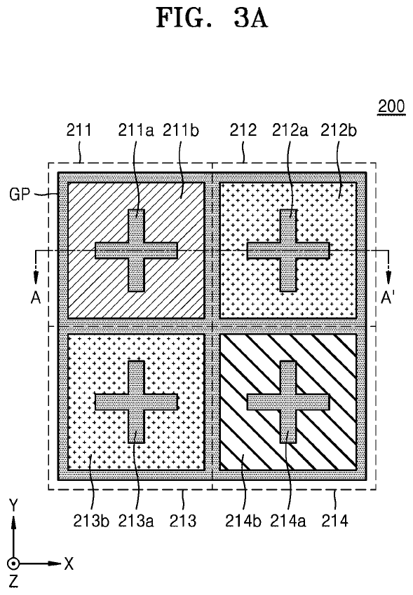

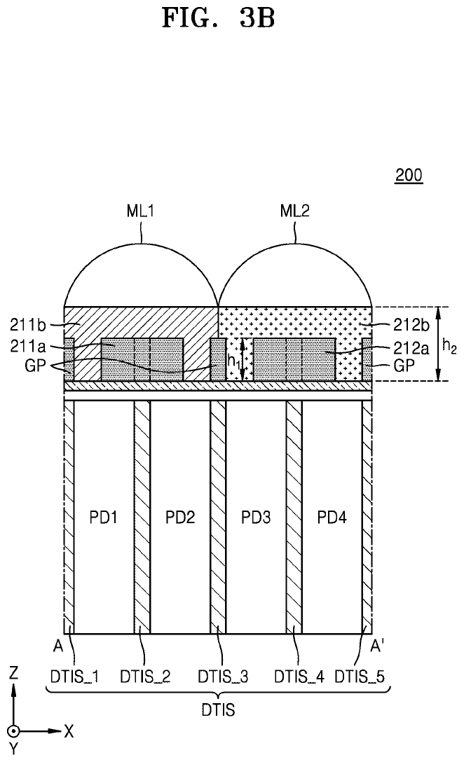

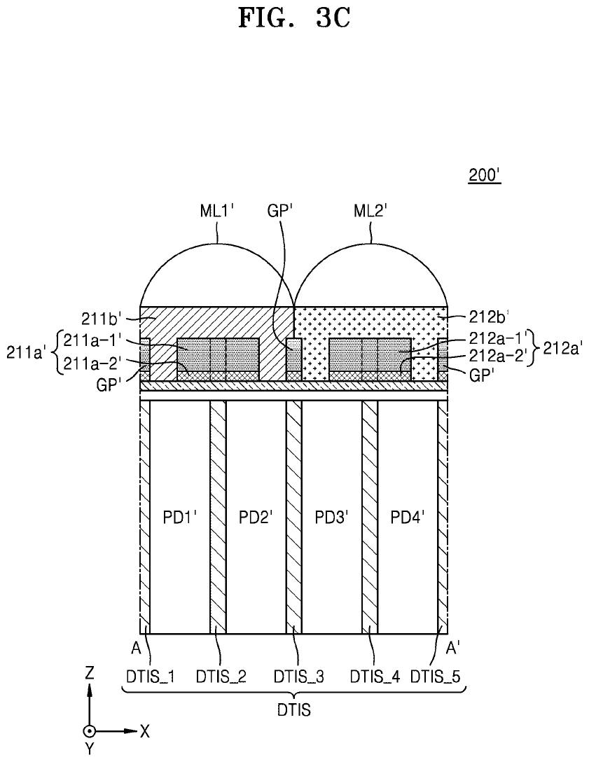

Meanwhile, a microlens ML1 or ML2 in FIG. 3B for light collection may be above each of the plurality of pixels PX or above each of pixel groups including adjacent pixels PX. Each of the plurality of pixels PX may sense light of a specific spectral region from light received through the microlens ML1 or ML2 in FIG. 3B arranged thereabove.

The pixel array 110 may include at least one autofocusing (AF) pixel. An AF pixel may be a pixel having a circuit or physical structure for autofocusing. In an implementation, a grid structure may be in a color filter array above an AF pixel.

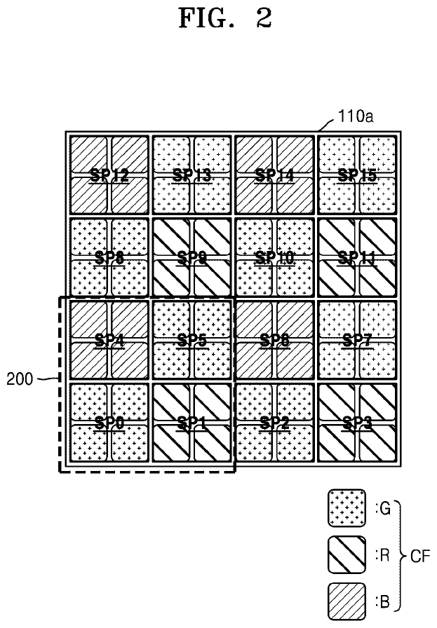

A color filter array (CF in FIG. 2) for transmitting light of a specific spectral region may be above the plurality of pixels PX, and a color detectable by a pixel may be determined according to a color filter above each of the plurality of pixels PX. The color filter array CF may include grid structures 211a, 212a, 213a, and 214a in FIG. 3A. The color filter array CF may improve focusing and sensitivity of AF pixels by including the grid structures 211a, 212a, 213a, and 214a in FIG. 3A. Grid structures are described below in detail with reference to FIG. 3A and the subsequent drawings.

The row driver 120 may drive the pixel array 110 in units of rows. The row driver 120 may decode a row control signal (e.g., an address signal) received from the timing controller 190 and select at least one of row lines constituting the pixel array 110 in response to the decoded row control signal. In an implementation, the row driver 120 may generate a selection signal for selecting one of a plurality of rows. In addition, the pixel array 110 may output a pixel signal, e.g., a pixel voltage, from a row selected by the selection signal provided from the row driver 120. The pixel signal may include a reset signal and an image signal. The row driver 120 may transmit control signals for outputting a pixel signal to the pixel array 110, and the pixel PX may output a pixel signal by operating in response to the control signals.

The ramp signal generator 130 may generate a ramp signal (e.g., a ramp voltage) of which a level may rise or fall with a certain slope under the control of the timing controller 190. A ramp signal RAMP may be provided to each of a plurality of correlated double sampling (CDS) circuits 160 in the ADC circuit 150.

The counting code generator 140 may generate a counting code CCD under the control by the timing controller 190. The counting code CCD may be provided to each of a plurality of counter circuits 170. In some embodiments, the counting code generator 140 may be implemented as a gray code generator. The counting code generator 140 may generate, as the counting code CCD, a plurality of code values having a resolution according to a set number of bits. In an implementation, when a 10-bit code is set, the counting code generator 140 may generate the counting code CCD including 1024 code values which may sequentially increase or decrease.

The ADC circuit 150 may include the plurality of CDS circuits 160 and the plurality of counter circuits 170. The ADC circuit 150 may convert a pixel signal (e.g., a pixel voltage) input from the pixel array 110 into a pixel value, which may be a digital signal. Each pixel signal received through each of a plurality of column lines CL may be converted into a pixel value, which may be a digital signal, by each of the CDS circuits 160 and counter circuits 170.

The CDS circuit 160 may compare a pixel signal, e.g., a pixel voltage, received through the column line CL, to the ramp signal RAMP, and output a result of the comparison as a comparison result signal. When a level of the ramp signal RAMP is the same as a level of the pixel signal, the CDS circuit 160 may output a comparison signal that may be transitioned from a first level (e.g., logic high) to a second level (e.g., logic low). A time point at which a level of the comparison signal is transitioned may be determined according to the level of the pixel signal.

The CDS circuit 160 may sample a pixel signal provided from the pixel PX according to a CDS method. The CDS circuit 160 may sample a reset signal received as a pixel signal and compare the reset signal to the ramp signal RAMP to generate a comparison signal according to the reset signal. Afterwards, the CDS circuit 160 may sample an image signal correlated to the reset signal and compare the image signal to the ramp signal RAMP to generate a comparison signal according to the image signal.

The counter circuit 170 may count a level transition time point of a comparison result signal output from the CDS circuit 160 and output a count value. In some embodiments, the counter circuit 170 may include a latch circuit and an arithmetic circuit. The latch circuit may receive the counting code CCD from the counting code generator 140 and a comparison signal from the CDS circuit 160, and latch a code value of the counting code CCD at a time point at which a level of the comparison signal may be transitioned. The latch circuit may latch each of a code value, e.g., a reset value, corresponding to a reset signal, and a code value, e.g., an image signal value, corresponding to an image signal. The arithmetic circuit may calculate the reset value and the image signal value to generate an image signal value from which a reset level of the pixel PX may be removed. The counter circuit 170 may output, as a pixel value, the image signal value from which the reset level may be removed.

The data output circuit 180 may temporarily store a pixel value output from the ADC circuit 150 and then output the pixel value. The data output circuit 180 may include a plurality of column memories 181 and a column decoder 182. Each of the plurality of column memories 181 stores a pixel value received from the counter circuit 170. In some embodiments, each of the plurality of column memories 181 may be in the counter circuit 170. A plurality of pixel values stored in the plurality of column memories 181 may be output as image data IDT under the control by the column decoder 182.

The timing controller 190 may output a control signal to each of the row driver 120, the ramp signal generator 130, the counting code generator 140, the ADC circuit 150, and the data output circuit 180 to control an operation or timing of each of the row driver 120, the ramp signal generator 130, the counting code generator 140, the ADC circuit 150, and the data output circuit 180.

A processor 1200 connected to the image sensor 100 may perform noise reduction processing, gain adjustment, waveform shaping processing, interpolation processing, white balance processing, gamma processing, edge enhancement processing, and binning on the image data IDT. In some embodiments, the processor 1200 may be in the image sensor 100.

The image sensor 100 may convert incident light into an image signal. The image sensor 100 may be included in an electronic apparatus. In an implementation, an electronic apparatus including the image sensor 100 may have an image or light sensing function. In an implementation, the electronic apparatus may be one of a camera, a smartphone, a wearable device, an Internet of things (IOT), a tablet personal computer (PC), a personal digital assistant (PDA), a portable multimedia player (PMP), a navigation apparatus. In an implementation, the electronic apparatus may be provided as a component in vehicles, furniture, manufacturing equipment, doors, or various measuring instruments.

FIG. 2 is a diagram of a pixel array corresponding to a color filter array, according to an example embodiment. Referring to FIG. 2, a pixel array 110a may include a plurality of pixels along a plurality of rows and columns, and e.g., each shared pixel defined as a unit including pixels arranged in two rows and two columns may include four subpixels. The pixel array 110a may include first to sixteenth shared pixels SP0 to SP15. The pixel array 110a may further include the color filter array CF such that the first to sixteenth shared pixels SP0 to SP15 may sense various colors. In an implementation, the color filter array CF may include filters that sense red R, green G, and blue B, and each of the first to sixteenth shared pixels SP0 to SP15 may include subpixels in which the same color filter may be arranged. In an implementation, each of the fifth shared pixel SP4, the seventh shared pixel SP6, the thirteenth shared pixel SP12, and the fifteenth shared pixel SP14 may include subpixels including a color filter for the blue B, each of the first shared pixel SP0, the third shared pixel SP2, the sixth shared pixel SP5, the eighth shared pixel SP7, the ninth shared pixel SP8, the eleventh shared pixel SP10, the fourteenth shared pixel SP13, and the sixteenth shared pixel SP15 may include subpixels including a color filter for the green G, and each of the second shared pixel SP1, the fourth shared pixel SP3, the tenth shared pixel SP9, and the twelfth shared pixel SP11 may include subpixels including a color filter for the red R.

In an implementation, each of a group including the first shared pixel SP0, the second shared pixel SP1, the fifth shared pixel SP4, and the sixth shared pixel SP5, a group including the third shared pixel SP2, the fourth shared pixel SP3, the seventh shared pixel SP6, and the eighth shared pixel SP7, a group including the ninth shared pixel SP8, the tenth shared pixel SP9, the thirteenth shared pixel SP12, and the fourteenth shared pixel SP13, and a group including the eleventh shared pixel SP10, the twelfth shared pixel SP11, the fifteenth shared pixel SP14, and the sixteenth shared pixel SP15 may correspond to a block of the color filter array CF.

The pixel array 110a according to an embodiment may include various types of color filters. In an implementation, the color filter array CF may include filters that sense not only red, green and blue colors but also yellow, cyan, magenta, white colors. In addition, the pixel array 110a may include more shared pixels, and the arrangement of each of the first to sixteenth shared pixels SP0 to SP15 may be implemented in various ways.

FIG. 3A is a diagram of a planar layout of an image sensor 200 according to an example embodiment. Referring to FIG. 3A, a planar layout diagram of an image sensor 200 corresponding to first, second, fifth, and sixth shared pixels SP0, SP1, SP4, and SP5 indicated by a dotted line in the pixel array 110a in FIG. 2 is shown. For convenience of explanation, hereinafter, the four shared pixels shown in FIG. 3A may be referred to as a first shared pixel region 211, a second shared pixel region 212, a third shared pixel region 213, and a fourth shared pixel region 214, respectively.

A shared pixel region may mean a region in which a shared pixel including a plurality of subpixels may be arranged. Each shared pixel region may include a photoelectric conversion region corresponding to subpixels included in a corresponding shared pixel, a color filter region corresponding to the corresponding shared pixel, and a microlens above the color filter region.

Each of the first shared pixel region 211, the second shared pixel region 212, the third shared pixel region 213, and the fourth shared pixel region 214 may include four subpixels. Referring to FIG. 3A, the first shared pixel region 211 may include a first grid structure 211a and a first color filter region 211b. The second shared pixel region 212 may include a second grid structure 212a and a second color filter region 212b. The third shared pixel region 213 may include a third grid structure 213a and a third color filter region 213b. The fourth shared pixel region 214 may include a fourth grid structure 214a and a fourth color filter region 214b. The first grid structure 211a to the fourth grid structure 214a may be arranged at central portions of the first color filter region 211b to the fourth color filter region 214b, respectively. In an implementation, the first grid structure 211a to the fourth grid structure 214a may each be located at an intersection of a plurality of subpixels included in each of the first shared pixel region 211 to the fourth shared pixel region 214. According to an example of FIG. 3A, the first grid structure 211a to the fourth grid structure 214a may be in the form of a cross.

Referring to an example of FIG. 3A, the first shared pixel region 211, the second shared pixel region 212, the third shared pixel region 213, and the fourth shared pixel region 214 may further include a grid pattern GP for separating the respective shared pixel regions from each other. In an implementation, the grid pattern GP may be in a color filter region.

Hereinafter, the first grid structure 211a is mainly described to prevent redundant description. The characteristics of the first grid structure 211a may be equally applied to the second grid structure 212a, the third grid structure 213a, and the fourth grid structure 214a.

FIG. 3B is a cross-sectional view of the layout taken along line A-A′ of FIG. 3A. Referring to FIG. 3B, cross-sectional views of the first shared pixel region 211 and second shared pixel region 212 may be provided. The first shared pixel region 211 may include first photoelectric conversion regions PD1 and PD2, the first color filter region 211b, and the first microlens ML1. The second shared pixel region 212 may include second photoelectric conversion regions PD3 and PD4, the second color filter region 212b, and the second microlens ML2. The first and second photoelectric conversion regions PD1, PD2, PD3, and PD4 may each correspond to a photodiode included in each subpixel. The first and second photoelectric conversion regions PD1, PD2, PD3, and PD4 may be physically separated from each other through a deep trench isolation (DTI) structure DTIS. The DTI structure DTIS may be formed in various ways, such as front deep trench isolation (FDTI), backside deep trench isolation (BDTI), and hybrid deep trench isolation (HDTI).

Referring to FIG. 3B, the first grid structure 211a, the second grid structure 212a, and the DTI structure DTIS may be located in different regions of the image sensor 200. The first grid structure 211a and the second grid structure 212a may be in the first color filter region 211b and the second color filter region 212b, respectively. The DTI structure DTIS may be located in the first and second photoelectric conversion regions PD1, PD2, PD3, and PD4. The grid pattern GP having the same length as a width of the DTI structure DTIS and having the same height as that of the first grid structure 211a and the second grid structure 212a may be above the DTI structure DTIS.

Referring to FIG. 3B, the first grid structure 211a and the second grid structure 212a may have the same height, that is, a height h1. The height h1 of the first and second grid structures 211a and 212a may be smaller than a height h2 of the first and second color filter regions 211b and 212b. Since the height h1 of the first and second grid structures 211a and 212a may be smaller than the height h2 of the first and second color filter regions 211b and 212b, excessive scattering may be prevented.

A material of the first grid structure 211a and second grid structure 212a may be a material other than metal. A material of the first grid structure 211a and the second grid structure 212a may be a material having a small refractive index. A material of the first grid structure 211a and the second grid structure 212a may be one of nitride and oxide.

The first grid structure 211a may be at the central portion of the first color filter region 211b. The first grid structure 211a may be above a central DTI structure DTIS_2 separating the first photoelectric conversion regions PD1 and PD2 of the first shared pixel region 211 from each other.

FIG. 3B illustrates only the first grid structure 211a and the second grid structure 212a of the image sensor 200, but the characteristics of the first grid structure 211a and the second grid structure 212a may be equally applied to the third grid structure 213a and the fourth grid structure 214a of the image sensor 200.

FIG. 3C is another example of a cross-sectional view of the layout of the image sensor 200 taken along line A-A′ of FIG. 3A. In the description of FIG. 3C, redundant description of the same parts as those in the embodiment of FIG. 3B is omitted. Referring to FIG. 3C, a first grid structure 211a′ may include a first material layer 211a-1′ and a second material layer 211a-2′, which include different materials, and a second grid structure 212a′ may include a first material layer 212a-1′ and a second material layer 212a-2′, which include different materials. In an implementation, the first material layers 211a-1′ and 212a-1′ may be above the second material layers 211a-2′ and 212a-2′, respectively. In an implementation, the first material layers 211a-1′ and 212a-1′ may be provided with a material other than metal, and the second material layers 211a-2′ and 212a-2′ may be provided with a metal material. In an implementation, the first material layers 211a-1′ and 212a-1′ may be one of nitride or oxide. The first material layers 211a-1′ and 212a-1′ may be a material having a small refractive index. In an implementation, a height of the first material layers 211a-1′ and 212a-1′ may be larger than a height of the second material layers 211a-2′ and 212a-2′. In an implementation, since metal has a property of absorbing light, when an upper surface of the first grid structure 211a′, on which light passing through a microlens ML1″ may be focused is metal, light may be lost.

Referring to FIG. 3C, a grid pattern GP′ having the same length as a width of the DTI structure DTIS and having the same height as that of the first grid structure 211a′ and the second grid structure 212a′ may be above the DTI structure DTIS.

According to the embodiments of FIGS. 3B and 3C, the upper surface of the first grid structure, to which light passing through the microlens is first applied, may be provided with a material other than metal to maximize AF capability.

In an implementation, subpixels included in a shared pixel region may be an AF pixel. In the AF pixel, as a difference between a left signal, a right signal, an upper signal, and a lower signal of the subpixels included in the AF pixel increases, discriminating power may be increased and AF capability may be improved. Sensitivity may mean an amount of electrons absorbed by a photodiode per unit time and per unit illuminance.

According to an embodiment, sensitivity may be further increased by using a material other than metal for the upper surface of the first grid structure. According to an embodiment, a plurality of subpixels included in a shared pixel region may be separated from each other by including a grid structure at a central portion of a color filter region, and thus, the capability to distinguish between the plurality of subpixels may increase. Accordingly, AF characteristics may be improved, and at the same time, sensitivity may be improved.

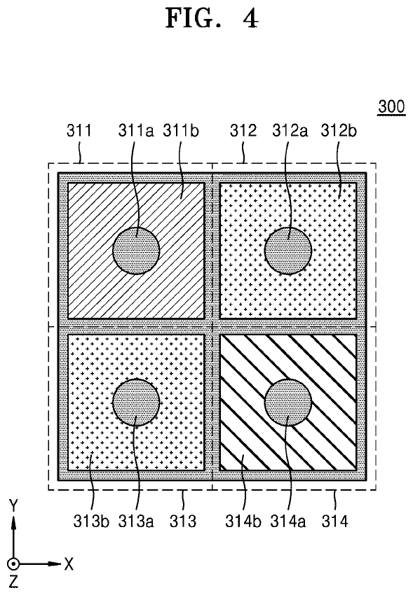

FIGS. 4 to 8 are diagrams of planar layouts of image sensors according to example embodiments. In the description of FIGS. 4 to 8, description redundant to the description made with reference to FIGS. 3A to 3C is omitted. Referring to FIGS. 4 to 8, planar layouts of image sensors are described.

Referring to embodiments illustrated in FIGS. 4 to 7, an image sensor 300 may include first to fourth shared pixel regions 311, 312, 313, and 314, an image sensor 400 may include first to fourth shared pixel regions 411, 412, 413, and 414, an image sensor 500 may include first to fourth shared pixel regions 511, 512, 513, and 514, an image sensor 600 may include first to fourth shared pixel regions 611, 612, 613, and 614. Shapes of grid structures included in the image sensors 300, 400, 500, and 600 of FIGS. 4 to 7 may be different from each other.

Referring to FIG. 4, an image sensor 300 may include a first grid structure 311a, a second grid structure 312a, a third grid structure 313a, and a fourth grid structure 314a respectively included in the first shared pixel region 311, the second shared pixel region 312, the third shared pixel region 313, and the fourth shared pixel region 314, and each grid structure may have a circular shape.

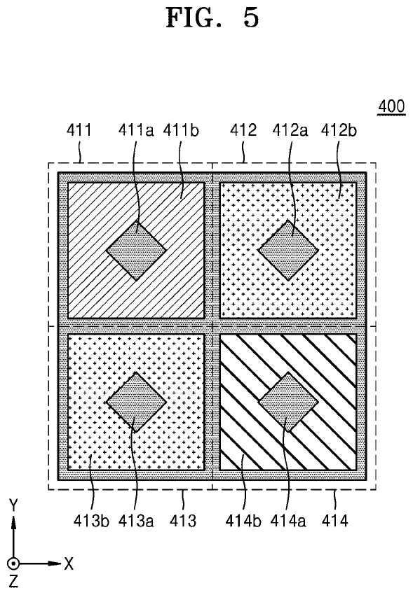

Referring to FIG. 5, an image sensor 400 may include a first grid structure 411a, a second grid structure 412a, a third grid structure 413a, and a fourth grid structure 414a respectively included in the first shared pixel region 411, the second shared pixel region 412, the third shared pixel region 413, and the fourth shared pixel region 414, and each grid structure may have a rhombus shape.

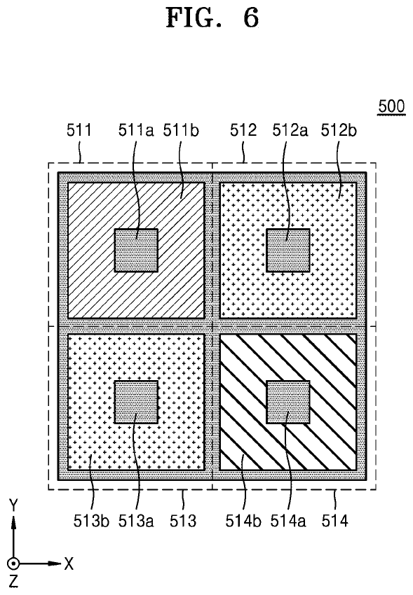

Referring to FIG. 6, an image sensor 500 may include a first grid structure 511a, a second grid structure 512a, a third grid structure 513a, and a fourth grid structure 514a respectively included in the first shared pixel region 511, the second shared pixel region 512, the third shared pixel region 513, and the fourth shared pixel region 514, and each grid structure may have a square shape.

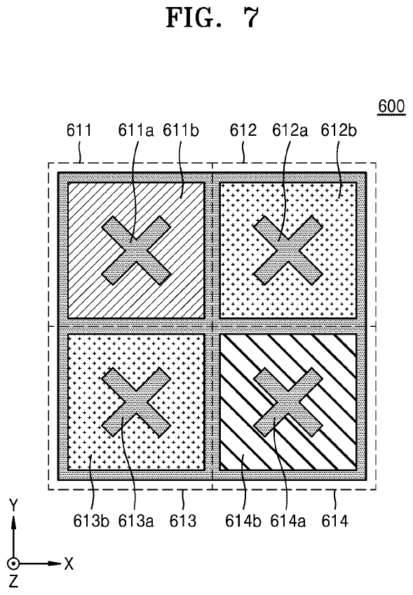

Referring to FIG. 7, an image sensor 600 may include a first grid structure 611a, a second grid structure 612a, a third grid structure 613a, and a fourth grid structure 614a respectively included in the first shared pixel region 611, the second shared pixel region 612, the third shared pixel region 613, and the fourth shared pixel region 614, and each grid structure may have an X shape.

Referring to the embodiments of FIGS. 4 to 7, the grid structures included in each of the image sensors 300, 400, 500, and 600 may have various shapes. According to the embodiments of FIGS. 4 to 7, the grid structures included in each of the image sensors 300, 400, 500, and 600 may be arranged at central portions of the respective shared pixel regions, and thus, light applied to a plurality of subpixels included in each of the shared pixel regions may be separated. According to the embodiments of FIGS. 4 to 7, when viewed from above, the grid structures included in each of the image sensors 300, 400, 500, and 600 may not be in contact with edges of color filter regions. According to the embodiments of FIGS. 4 to 7, the grid structures included in each of the image sensors 300, 400, 500, and 600 may be provided in a vertically and bilaterally symmetrical structure. The shape of the grid structure may also be provided in a non-symmetrical structure.

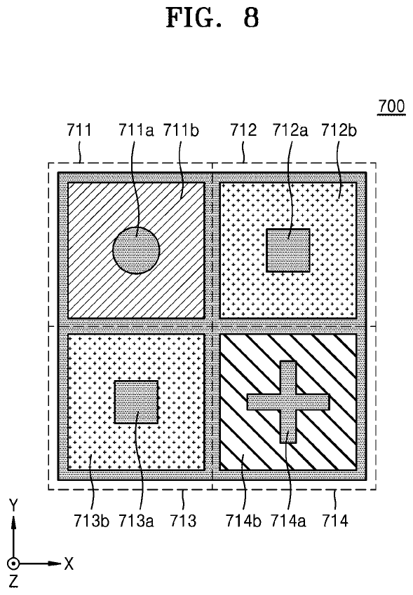

Referring to the embodiment of FIG. 8, the image sensor 700 may include the first shared pixel region 711, the second shared pixel region 712, the third shared pixel region 713, and the fourth shared pixel region 714.

A first grid structure 711a included in the first shared pixel region 711, a second grid structure 712a included in the second shared pixel region 712, and a fourth grid structure 714a included in the fourth shared pixel region 714 may have different shapes. Referring to the embodiment of FIG. 8, the first grid structure 711a may have a circular shape. The second grid structure 712a and the third grid structure 713a may each have a square shape. The fourth grid structure 714a may have a cross shape.

Referring to the embodiment of FIG. 8, the first shared pixel region 711, the second shared pixel region 712, the third shared pixel region 713, and the fourth shared pixel region 714 may correspond to respective colors included in color filter regions. The first shared pixel region 711 may correspond to a blue color filter region. The second shared pixel region 712 and the third shared pixel region 713 may each correspond to a green color filter region. The fourth shared pixel region 714 may correspond to a red color filter region.

Referring to FIG. 8, the grid structures respectively included the different color filter regions may have different structures. The grid structures may each have a shape capable of well reflecting a corresponding frequency wavelength in consideration of a wavelength of a color filter region in which a corresponding grid structure may be arranged.

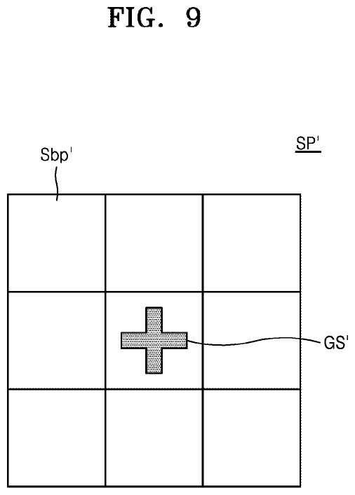

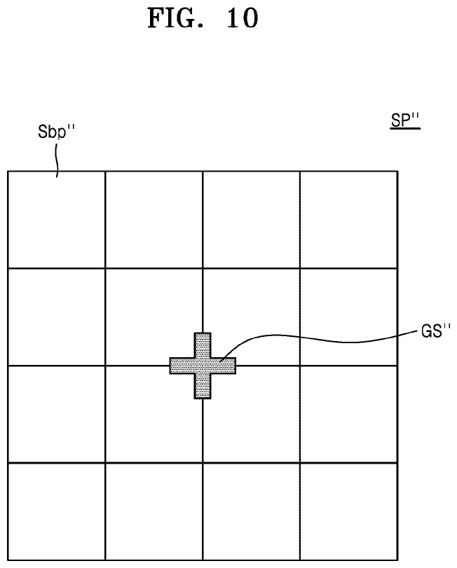

FIGS. 9 and 10 are diagrams for explaining a grid structure arranged in a pixel array, according to example embodiments. Referring to a pixel array of FIG. 9, a shared pixel region SP′ may include nine subpixels Sbp′. In some embodiments, a shared pixel included in the shared pixel region SP′ may be referred to as a nona cell. Referring to the shared pixel region SP′ of FIG. 9, when the shared pixel region SP′ includes the nine subpixels Sbp′, a grid structure GS' may be provided in a subpixel arranged at a central portion of the nine subpixels Sbp′. According to an example of FIG. 9, the grid structure GS' may have a smaller size than that of the subpixel Sbp′, but the grid structure GS' may have the same size as that of the subpixel Sbp′ or may have a larger size than that of the subpixel Sbp′.

Referring to a pixel array of FIG. 10, a shared pixel region SP″ may include 16 subpixels Sbp“. In some embodiments, a shared pixel included in the shared pixel region SP” may be referred to as a hexadeca cell. Referring to the shared pixel region SP″ of FIG. 10, when the shared pixel region SP″ includes the 16 subpixels Sbp″, a grid structure GS″ may be at a center point of subpixels located at a central portion of the 16 subpixels Sbp″. In the shared pixel region SP″ of FIG. 10, the grid structure GS″ may have a smaller size than that of the subpixel Sbp″, but the grid structure GS″ may have the same size as that of the subpixel Sbp″ or may have a larger size than that of the subpixel Sbp″.

Referring to FIGS. 9 and 10, the shared pixel regions include subpixels having the same color filter and adjacent to each other, and one shared pixel region may include one microlens. It is shown as an example that each of the shared pixel regions shown in FIGS. 9 and 10 includes subpixels in an N*N arrangement. N may be a natural number of 2 or more.

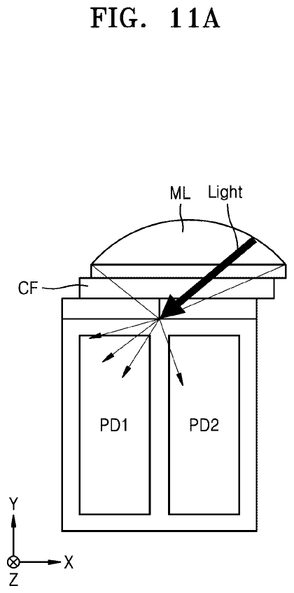

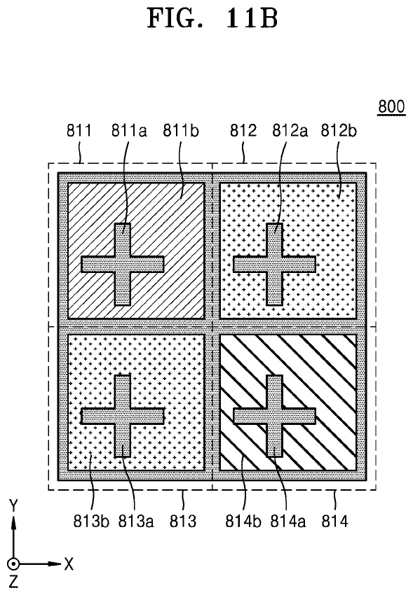

FIGS. 11A and 11B are diagrams of an image sensor according to an example embodiment. Referring to FIG. 11A, a microlens ML above the color filter array CF may be shifted in an X-axis direction. The microlens ML may be shifted in the X-axis direction along a shift line. Arrangement positions of the microlens ML may vary according to a position relative to a module lens included in an imaging unit of an electronic apparatus including an image sensor. As the microlens ML becomes farther away from a center point of the module lens, the microlens ML may be shifted toward the center point of the module lens.

FIG. 11B illustrates an image sensor 800 including a grid structure included in a shared pixel region in which the microlens ML may be shifted according to an embodiment of FIG. 11A. Referring to FIG. 11B, grid structures 811a, 812a, 813a, and 814a may be arranged diagonally from central portions of shared pixel regions 811, 812, 813, and 814, respectively. In an implementation, arrangement positions of the grid structures 811a, 812a, 813a, and 814a may vary according to shift directions of microlenses.

In an implementation, when a microlens is not shifted, a grid structure may be at a position sharing a center point of a shared pixel region, which is shown in the embodiments of FIGS. 4 to 8.

According to an embodiment, when a microlens is shifted, a grid structure may also be shifted in a direction in which the microlens is shifted, which is shown in FIG. 11B.

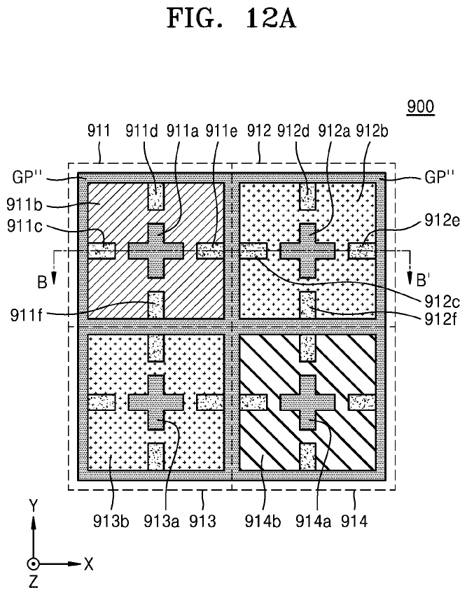

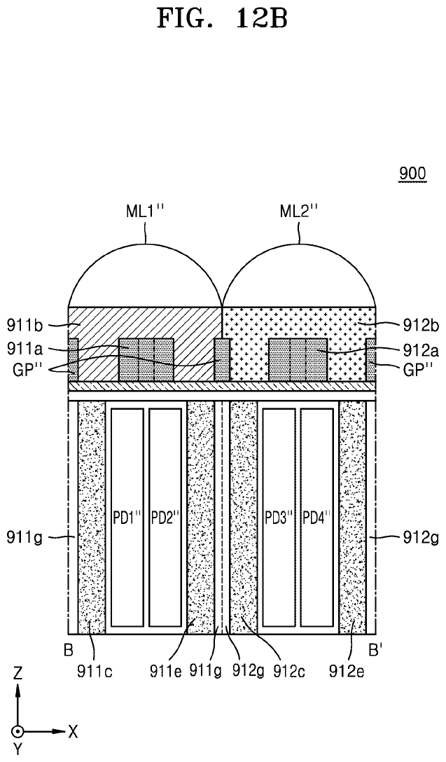

FIG. 12A is a diagram of a planar layout of an image sensor 900 according to an example embodiment. In describing an embodiment of FIG. 12A, description of the same features as those described with reference to FIG. 3A is omitted. Referring to FIG. 12A, it is shown as an embodiment that an image sensor 900 includes a first shared pixel region 911, a second shared pixel region 912, a third shared pixel region 913, and a fourth shared pixel region 914. Hereinafter, only the first shared pixel region 911 is described to prevent redundant description.

Referring to FIGS. 12A and 12B, the first shared pixel region 911 may include a first separation element 911g, a second separation element 911c, a third separation element 911d, a fourth separation element 911e, and a fifth separation element 911f The first to fifth separation elements 911g, 911c, 911d, 911e, and 911f may be on the same layer as a photoelectric conversion region. In an implementation, the first separation element 911g may be an element for separating the first shared pixel region 911 from the second shared pixel region 912 and the third shared pixel region 913, adjacent thereto. In an implementation, a grid pattern GP″ may be above the first separation element 911g. Referring to FIG. 12A, since FIG. 12A is a view from above, the first separation element 911g may be under the grid pattern GP″. The second separation element 911c, the third separation element 911d, the fourth separation element 911e, and the fifth separation element 911f may be separation elements in the first shared pixel region 911. In an implementation, the second separation element 911c, the third separation element 911d, the fourth separation element 911e, and the fifth separation element 911f may not be in contact with each other. Each of the second separation element 911c, the third separation element 911d, the fourth separation element 911e, and the fifth separation element 911f may be in contact with the first separation element 911g. The second separation element 911c and the fourth separation element 911e may extend from the first separation element 911g in an X-axis direction. The third separation element 911d and the fifth separation element 911f may extend from the first separation element 911g in a Y-axis direction. In an implementation, the second separation element 911c may be in contact with a central portion of a first side surface of the first separation element 911g and may extend in the X-axis direction. The third separation element 911d may be in contact with a central portion of a second side surface of the first separation element 911g and may extend in the Y-axis direction. The fourth separation element 911e may be in contact with a central portion of a third side surface of the first separation element 911g and may extend in the X-axis direction. The fifth separation element 911f may be in contact with a central portion of a fourth side surface of the first separation element 911g and may extend in the Y-axis direction.

According to the embodiment of FIG. 12A, the first shared pixel region 911 may share one floating diffusion node. According to the embodiment of FIG. 12A, the first shared pixel region 911 may be in a DCI center cut (DCC) structure. According to the embodiment of FIG. 12A, a first color filter region 911b may include a first grid structure 911a. According to the embodiment of FIG. 12A, in the case of an image sensor in a DCC structure, photoelectric conversion regions of a plurality of subpixels included in the first shared pixel region 911 may not be completely separated from each other. According to the embodiment of FIG. 12A, since the second separation element 911c, the third separation element 911d, the fourth separation element 911e, and the fifth separation element 911f may not be in contact with each other, photoelectric conversion regions may not be completely separated from each other and may share one floating diffusion node. In the embodiment of FIG. 12A, light applied to a plurality of photoelectric conversion regions may be primarily separated from the first color filter region 911b by including the first grid structure 911a in the first color filter region 911b. In an implementation, the first grid structure 911a may not overlap the second separation element 911c, the third separation element 911d, the fourth separation element 911e, and the fifth separation element 911f, when viewed from above. In an implementation, the first grid structure 911a may have a cross shape. In an implementation, the first grid structure 911a may be apart from the second separation element 911c, the third separation element 911d, the fourth separation element 911e, and the fifth separation element 911f by the same distance in the X-axis direction or the Y-axis direction.

FIG. 12B is a cross-sectional view of the layout taken along line B-B′ of FIG. 12A. Referring to FIG. 12B, the first color filter region 911b may include the first grid structure 911a, and a second color filter region 912b may include a second grid structure 912a. Referring to FIG. 12B, the first color filter region 911b and the second color filter region 912b may further include the grid pattern GP″ separating the first color filter region 911b and the second color filter region 912b from each other.

Referring to the cross-sectional view of the layout taken along line B-B′ of FIG. 12A, the second separation element 911c and the fourth separation element 911e may be under the first grid structure 911a. When compared to the embodiment of FIG. 3B, a structure in which photoelectric conversion regions PD1″ and PD2″ are not separated by a separate separation film is shown. Light applied to the photoelectric conversion regions PD1″ and PD2″ may be separated by the first grid structure 911a included in the first color filter region 911b to correspond to each subpixel. Referring to FIG. 12B showing the cross-sectional view, a height of the first grid structure 911a may be smaller than a height of the first color filter region 911b. The first grid structure 911a may be a material having a small refractive index, other than metal. The first grid structure 911a may be nitride or oxide.

FIGS. 12A and 12B illustrate that the grid structure may have a cross shape. In an implementation, the grid structure may be an X shape, a circular shape, a rhombus shape, or a quadrangular shape.

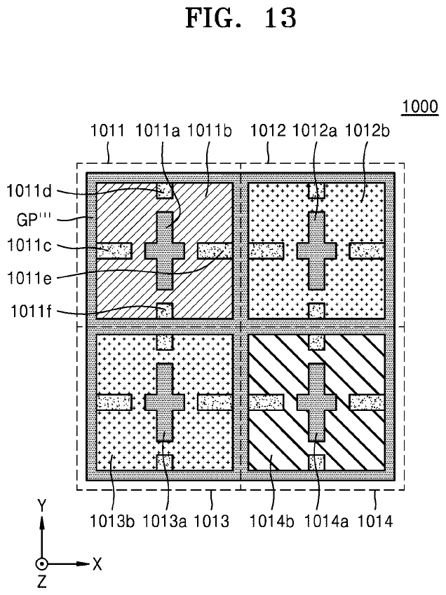

FIG. 13 is a diagram of a planar layout of an image sensor 1000 according to an example embodiment. In an embodiment of FIG. 13, description redundant to the description made with reference to FIG. 12A is omitted.

Referring to FIG. 13, a length of a second separation element 1011c in an X-axis direction and a length of a fourth separation element 1011e in the X-axis direction may be the same. A length of a third separation element 1011d in a Y-axis direction and a length of a fifth separation element 1011f in the Y-axis direction may be the same. In an implementation, the length of the second separation element 1011c in the X-axis direction may be larger than the length of the third separation element 1011d in the Y-axis direction.

Referring to FIG. 13, the shape of a first grid structure 1011a may vary according to lengths of the second separation element 1011c, the third separation element 1011d, the fourth separation element 1011e, and the fifth separation element 1011f. Referring to FIG. 13, the first grid structure 1011a may have a cross shape. The cross shape of the first grid structure 1011a may be shorter in the X-axis direction than in the Y-axis direction. FIGS. 12A to FIG. 13 illustrate that the first grid structure 1011a may have a cross shape.

By way of summation and review, an image sensor capable of an autofocusing (AF) operation is disclosed. Image sensors may be classified into charge-coupled devices (CCDs) and complementary metal oxide semiconductors (CMOSs). CMOS image sensors may include a plurality of pixels that may be two-dimensionally arranged. Each of the plurality of pixels may include a photodiode (PD). The photodiode may convert incident light into an electrical signal. An image sensor may include a grid structure capable of maximizing auto focus and sensitivity characteristics. AF characteristics for focusing by using a phase difference between a plurality of pixels are important in image sensors.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor, comprising:
a plurality of first photoelectric conversion regions corresponding to a plurality of first subpixels;
a first color filter region above the plurality of first photoelectric conversion regions; and
a first microlens above the first color filter region, wherein:
the first color filter region includes a first grid structure at a central portion of the first color filter region, and
a height of the first grid structure is smaller than a height of the first color filter region.

2. The image sensor as claimed in claim 1, wherein the first grid structure has a shape vertically and bilaterally symmetrical with respect to the central portion of the first color filter region.

3. The image sensor as claimed in claim 1, wherein the first grid structure has a cross shape, an X shape, a circular shape, a rhombus shape, or a quadrangular shape.

4. The image sensor as claimed in claim 1, wherein the first grid structure is a material having a small refractive index, other than metal.

5. The image sensor as claimed in claim 1, wherein:
the first grid structure includes a first material layer; and a second material layer under the first material layer, and
the first material layer is a material having a small refractive index, other than metal.

6. The image sensor as claimed in claim 1, further comprising a second shared pixel region adjacent to a first shared pixel region including: the plurality of first photoelectric conversion regions; the first color filter region; and the first microlens,
wherein the second shared pixel region includes:
a plurality of second photoelectric conversion regions corresponding to a plurality of second subpixels;
a second color filter region above the plurality of second photoelectric conversion regions; and
a second microlens above the second color filter region,
the second color filter region includes a second grid structure arranged at a central portion of the second color filter region, and
a height of the second grid structure is smaller than a height of the second color filter region.

7. The image sensor as claimed in claim 6, wherein the first grid structure and the second grid structure have an identical shape.

8. The image sensor as claimed in claim 6, wherein the first grid structure and the second grid structure have different shapes.

9. The image sensor as claimed in claim 8, wherein the first color filter region and the second color filter region are color filters of different colors.

10. The image sensor as claimed in claim 1, wherein the plurality of first subpixels are subpixels arranged in an N*N form.

11. An image sensor, comprising:
a photoelectric conversion region corresponding to N*N subpixels;
a color filter region above the photoelectric conversion region; and
a microlens above the color filter region,
wherein the photoelectric conversion region includes:
a first separation element surrounding the photoelectric conversion region;
a second separation element in contact with a first side surface of the first separation element, in the photoelectric conversion region, and extending in an X-axis direction;
a third separation element in contact with a second side surface of the first separation element, in the photoelectric conversion region, and extending in a Y-axis direction;
a fourth separation element in contact with a third side surface of the first separation element, in the photoelectric conversion region, and extending in the X-axis direction; and
a fifth separation element in contact with a fourth side surface of the first separation element, in the photoelectric conversion region, and extending in the Y-axis direction,
the second separation element, the third separation element, the fourth separation element, and the fifth separation element are not in contact with each other, and
the color filter region includes a grid structure arranged at a central portion of the color filter region.

12. The image sensor as claimed in claim 11, wherein the grid structure does not overlap the second separation element, the third separation element, the fourth separation element, and the fifth separation element, when viewed from above.

13. The image sensor as claimed in claim 12, wherein the grid structure has a cross shape.

14. The image sensor as claimed in claim 13, wherein the grid structure is apart from the second separation element, the third separation element, the fourth separation element, and the fifth separation element by an identical distance in the X-axis direction or the Y-axis direction.

15. The image sensor as claimed in claim 11, wherein a height of the grid structure is smaller than a height of the color filter region.

16. The image sensor as claimed in claim 11, wherein the grid structure is a material having a small refractive index, other than metal.

17. The image sensor as claimed in claim 11, wherein the grid structure has an X shape, a circular shape, a rhombus shape, or a quadrangular shape.

18. An image sensor, comprising:
a plurality of photoelectric conversion regions corresponding to a plurality of subpixels;
a color filter region above the plurality of photoelectric conversion regions; and
a microlens above the color filter region, wherein:
the color filter region includes a grid structure,
the microlens is shifted in a first direction, and
the grid structure is shifted in the first direction with respect to a central portion of the color filter region.

19. The image sensor as claimed in claim 18, wherein the grid structure is a material having a small refractive index, other than metal.

20. The image sensor as claimed in claim 18, wherein a height of the grid structure is smaller than a height of the color filter region.
